(19) United States
(12) Patent Application Publication
(10) Pub. No.: US 2008/0242012 A1
(43) Pub. Date: Oct. 2, 2008

(54) High quality silicon oxynitride transition layer for high-k/metal gate transistors

(76) Inventors: Sangwoo Pae, Beaverton, OR (US); Jose Maiz, Portland, OR (US); Gilbert Dewey, Hillsboro, OR (US); Matthew V. Metz, Hillsboro, OR (US); Markus Kuhn, Portland, OR (US); Mark Doczy, Beaverton, OR (US); Jack Kavalieros, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/729,188

(22) Filed: Mar. 28, 2007

(51) Int. Cl. H01L 21/8234; H01L 21/336

(52) U.S. Cl. 438/197

(57) ABSTRACT

A method for fabricating a high quality silicon oxynitride layer for a high-k/metal gate transistor comprises depositing a high-k dielectric layer on a substrate, depositing a barrier layer on the high-k dielectric layer, wherein the barrier layer includes at least one of nitrogen or oxygen, depositing a capping layer on the barrier layer, and annealing the substrate at a temperature that causes at least a portion of the nitrogen and/or oxygen in the barrier layer to diffuse to an interface between the high-k dielectric layer and the substrate. The diffused nitrogen or oxygen forms a high-quality silicon oxynitride layer at the interface. The high-k dielectric layer, the barrier layer, and the capping layer may then be etched to form a gate stack for use in a high-k/metal gate transistor. The capping layer may be replaced with a metal gate electrode using a replacement metal gate process.

### BACKGROUND

To fabricate transistors at the 45 nanometer (nm) node and below, modern processes use high-k dielectric materials for the gate dielectric layer along with true metals for the gate electrode. Such devices may be referred to as high-k/metal gate transistors. The high-k gate dielectric layer is generally deposited directly on a silicon substrate and a metal gate electrode is formed on the high-k gate dielectric layer. The metal gate electrode may be formed using a subtractive process or a replacement metal gate process, as is known in the art.

Although unintended, a transition layer often forms between the substrate and the high-k gate dielectric layer. This transition layer is generally four to six angstroms (Å) in thickness and has properties very similar to silicon oxynitride. In fact, the transition layer is essentially a poor quality silicon oxynitride layer that arises from the wet cleans that occur on the silicon substrate prior to the high-k deposition. As a result, the reliability of the transistor may be poor. In addition, the thickness of this transition layer is difficult to control since the layer is not intentionally engineered. In some processes, the transition layer may be intentionally grown to ensure that a higher quality silicon oxynitride is provided. Depositing a high-k gate dielectric layer on top of the thermally grown silicon oxynitride, however, may present other quality issues due to the low temperature high-k processing step that is required. In addition, controlling the thickness of silicon oxynitride by thermal oxidation prior to high-k deposition can add extra process complexity.

### BRIEF DESCRIPTION OF THE DRAWINGS

FIG. 1 is a process flow for fabricating a high-quality transition layer between a gate dielectric layer and a substrate in a high-k/metal gate MOS transistor in accordance with an implementation of the invention.

FIGS. 2 through 9 illustrate the process flow that is described in FIG. 1.

FIGS. 10 through 13 illustrate a replacement metal gate process flow in accordance with an implementation of the invention.

### DETAILED DESCRIPTION

Described herein are systems and methods of forming a high quality transition layer between a substrate and a high-k gate dielectric layer. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide a process for fabricating a high-quality transition layer between a substrate and a high-k gate dielectric layer for a high-k/metal gate transistor. In implementations of the invention, the growth of this transition layer may be precisely engineered through the use of an oxygen and/or nitrogen rich barrier layer and an annealing process. In implementations of the invention, the high-quality transition layer may be formed at a thickness that ranges from 3 to 7 Å for various device applications. The quality of the transition layer addresses both the device performance and reliability issues.

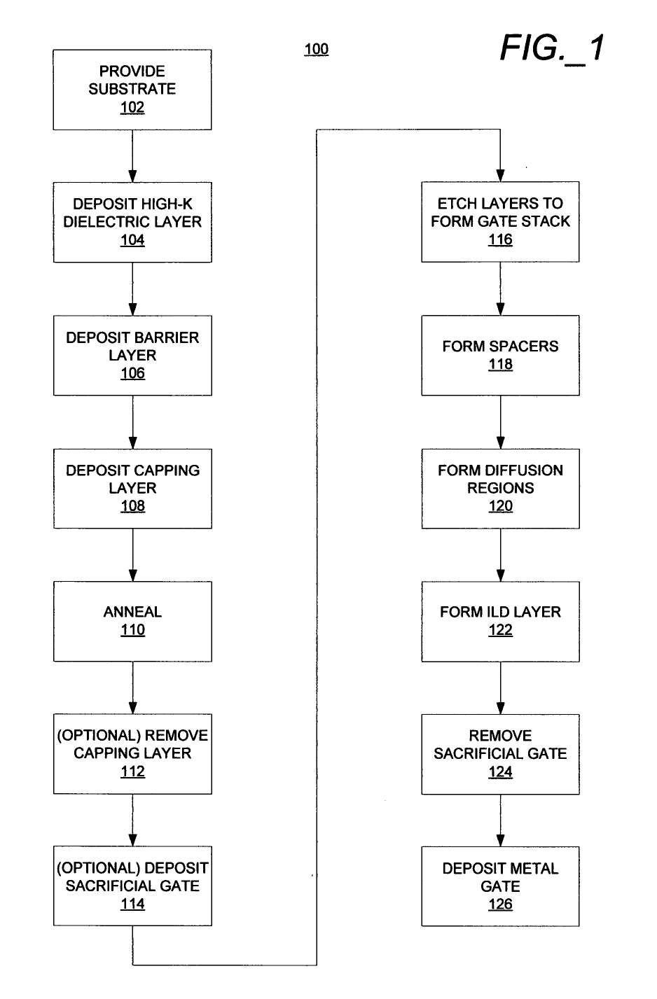

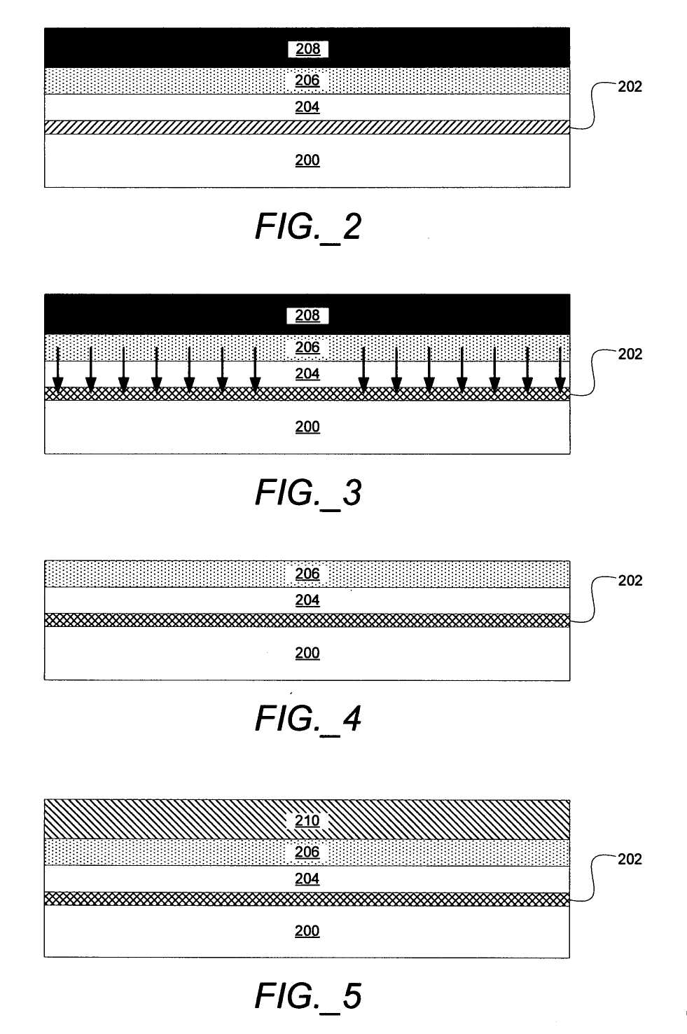

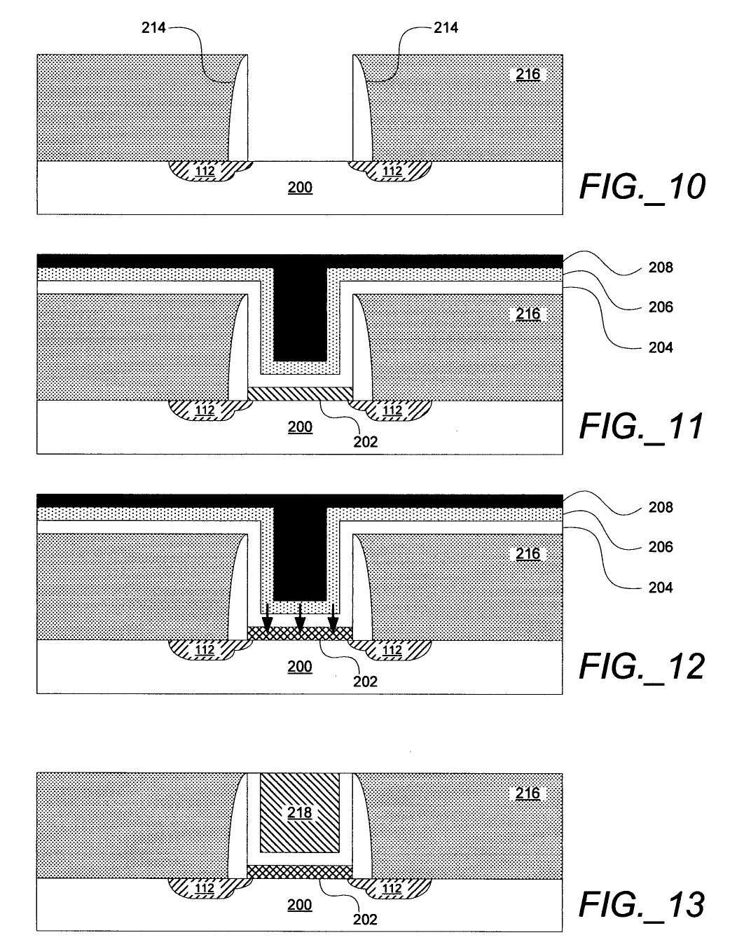

FIG. 1 is a process flow 100 for fabricating a high-quality transition layer between a gate dielectric layer and a substrate in a high-k/metal gate MOS transistor. FIGS. 2 through 9 illustrate the process flow 100 that is described in FIG. 1. It should be noted that while the process described in FIG. 1 and shown in FIGS. 2 through 9 provides a subtractive process for forming the gate stack of the high-k/metal gate MOS transistor, the process flow may be used in a replacement metal gate process as well, as shown in FIGS. 10 through 13.

The process flow 100 begins by providing a semiconductor substrate upon which the high-k/metal gate transistor may be formed (process 102 of FIG. 1). The semiconductor substrate may be formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

A high-k gate dielectric layer is deposited on the substrate (104). The gate dielectric material may be formed from materials such as silicon dioxide or high-k dielectric materials. Examples of high-k gate dielectric materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, the high-k gate dielectric layer may be between around 8 Angstroms (Å) to around 30 Å thick. In further embodiments, additional processing may be performed on the high-k gate dielectric layer, such as an annealing process to improve the quality of the high-k material. The high-k dielectric layer may be deposited using processes known in the art, including but not limited to a chemical vapor deposition (CVD) process, an atomic layer deposition (ALD) process, and a physical vapor deposition (PVD) process such as sputtering.

During deposition of the high-k dielectric layer, a poor quality transition layer is generally formed at the interface between the high-k dielectric layer and the substrate. This transition layer is generally 4 Å to 6 Å thick. As mentioned above, this transition layer is similar to silicon oxynitride in its nature but is of a lower quality than thermally grown silicon oxynitride since it arises mainly from the substrate surface chemical wet cleans prior to the high-K deposition.

The process flow 100 continues by forming a barrier layer over the high-k dielectric layer (106). In accordance with implementations of the invention, the barrier layer is used in conjunction with an annealing process to modify the transition layer and improve its quality. The extent of the modification that occurs to the transition layer may be controlled by way of the properties of the barrier layer, such as its composition and thickness. In one implementation of the invention for instance, at a given annealing temperature and time duration, a 15 Å thick barrier layer may produce a modified transition layer that is 5 Å thick while a 40 Å thick barrier layer may produce a modified transition layer that is 7 Å thick.

In implementations of the invention, the barrier layer may be formed from a material rich in nitrogen and/or oxygen. For instance, the barrier layer may be formed by using an ALD process to deposit a metal oxide or a metal nitride. In some implementations, the barrier layer may be formed by depositing a titanium oxynitride (TiNO) or tantalum oxynitride (TaNO) layer. In some implementations, a PVD or CVD process may be used to deposit the barrier layer. The thickness of the barrier layer may range from 10 Å to 40 Å, depending on the desired thickness of the modified transition layer. As mentioned above, a thicker barrier layer will produce a thicker transition layer.

The process flow 100 then continues by forming a capping layer on the barrier layer (108). The capping layer may be formed from materials such as polysilicon, sputtered silicon, silicon nitride, thick metal nitrides such as titanium nitride (TiN), and tantalum nitride (TaN). The thickness of the capping layer may range from 100 Å to 600 Å and also has an influence on the resulting thickness of the modified transition layer. This is because the capping layer helps prevent the ambient atmosphere from promoting too large a growth in the transition layer during the annealing process. In one implementation of the invention, for instance, at a given annealing temperature, time duration, and barrier layer thickness, a 120 Å thick capping layer may produce a modified transition layer that is 3 Å thick while a 40 Å thick barrier layer may produce a modified transition layer that is 7 Å thick.

FIG. 2 illustrates a semiconductor substrate 200 that includes the layers described above. As shown, a poor quality transition layer 202 is formed between the substrate 200 and a high-k gate dielectric layer 204. A barrier layer 206 rich in oxygen and/or nitrogen is formed atop the high-k dielectric layer 204. Finally, a capping layer 208 is formed over the barrier layer 206

Next, a high temperature annealing process may be carried out to modify the transition layer into a high-quality silicon oxynitride layer (110). This annealing process may also be used to improve the quality of the high-k material. The annealing process drives nitrogen and/or oxygen from the barrier layer into the transition layer, thereby modifying the transition layer and greatly improving its quality. In implementations of the invention, the annealing process may take place at a temperature that falls between around 600° C. and 1100° C. for a time duration that falls between around 1 second and 30 seconds. The annealing process may occur in an ambient atmosphere that contains an inert gas such as nitrogen, forming gas, or argon. Again, the resulting thickness of the modified transition layer may be controlled by varying parameters such as the annealing temperature, the annealing time duration, the thickness of the barrier layer, the thickness of the capping layer, and the composition of the annealing ambient atmosphere. In accordance with implementations of the invention, high quality silicon oxynitride transition layers that are at least 3 Å thick may be produced.

The annealing process is illustrated in FIG. 3 where oxygen and/or nitrogen is driven out of the barrier layer 206 and into the transition layer 202, thereby modifying the transition layer 202 and greatly improving its quality.

After the annealing process, the capping layer may optionally be removed (112). Conventional processes for removing the capping layer may be used, such as planarization processes (e.g., chemical mechanical polishing) or etching processes. Removal of the capping layer 208 is shown in FIG. 4. The decision on whether or not to remove the capping layer 208 will generally depend on whether the material used in the capping layer 208 may function as a sacrificial gate. If a material such as polysilicon is used, the capping layer 208 may be left on the barrier layer 206 to function as a sacrificial layer.

The process flow 100 may then continue with conventional CMOS fabrication processes. For example, if the capping layer is removed, either a metal gate electrode layer or a sacrificial gate electrode layer may be deposited atop the barrier layer for use in a subtractive or replacement metal gate process (114). If a metal gate electrode is used, the metal must consist of polysilicon or another conductive material that is able to withstand all of the annealing processes used, such as the anneals form the diffusion regions. If a sacrificial gate electrode layer is used, the layer may comprise a material such as polysilicon, silicon nitride, or any other material that is compatible with high temperature annealing processes used to form diffusion regions (e.g., a source region and a drain region) during fabrication of the CMOS device. The metal or sacrificial gate electrode layer may be deposited using a CVD process or a PVD process such as sputtering. The gate electrode layer may have a thickness that ranges from 400 Å to 800 Å. Alternately, as mentioned above, the capping layer may be left on the barrier layer to function as the sacrificial gate electrode layer. FIG. 5 illustrates the deposition of a metal or sacrificial gate electrode layer 210 on the barrier layer 206.

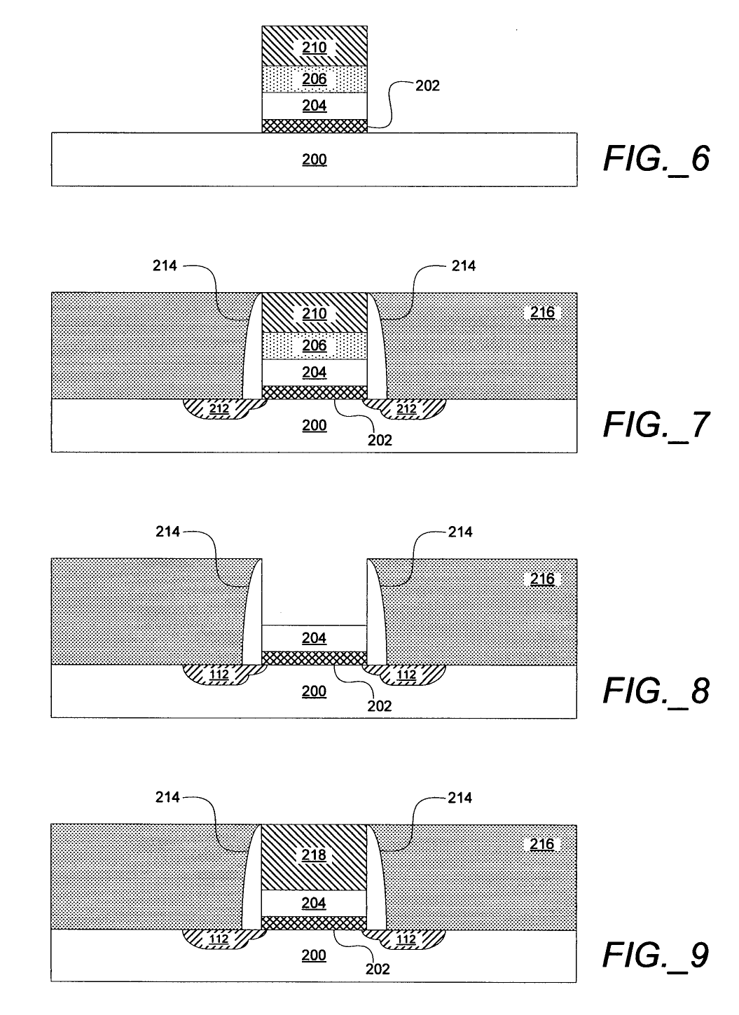

Next, as this is a subtractive process, the layers on the substrate may be patterned to form a gate stack on the substrate (116). Conventional patterning processes may be used here. For instance, one patterning process begins by depositing a photoresist material over the sacrificial layer and patterning the photoresist using ultraviolet radiation and an optical mask to define features such as the gate stack in the resist layer. The photoresist layer is developed to form a photoresist mask that protects the defined features, such as the portion of the underlying layers that will form the gate stack. An etchant is then applied to remove unprotected portions of the underlying layers, yielding a patterned gate stack as shown in FIG. 6.

Following formation of the gate stack, tip regions, diffusion regions, a pair of spacers, and an ILD layer are formed on the substrate. The spacers may be formed adjacent to the gate stack by depositing a material, such as silicon nitride or silicon dioxide, on the substrate and then etching the material to form the pair of spacers (118). After the spacers are formed, an ion implantation process may be used to implant dopants, such as boron, phosphorous, or arsenic, into the substrate adjacent the spacers to form diffusion regions and tip regions (120). An annealing process may follow the ion implantation process to drive the dopants further into the substrate and/or to activate the dopants. Alternately, the diffusion regions may be formed by etching regions of the substrate and epitaxially depositing a silicon or silicon-germanium based material into the etched regions to form the diffusion regions. These diffusion regions function as source and drain regions for the CMOS device.

Finally, a low-k dielectric material may be deposited and polished to form an ILD layer over the device (122). Low-k dielectric materials that may be used for the ILD layer include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layer may include pores or other voids to further reduce its dielectric constant. FIG. 7 illustrates the formation of diffusion regions 212 having tip regions, spacers 214, and an ILD layer 216 on the substrate 200.

At this point in the process flow 100, if the gate electrode layer 210 is formed of a metal gate electrode material, the gate stack may remain as is. Alternately, if the gate electrode layer 210 is formed of a sacrificial gate electrode material, a replacement metal gate process may be carried out to replace the sacrificial material with a metal gate electrode. In one implementation, the sacrificial gate electrode may be removed using conventional wet or dry etching processes (124). Such etching processes are well known in the art. The barrier layer may optionally be removed during this process. This is shown in FIG. 8 where the sacrificial layer 210 and the barrier layer 206 are removed and a trench is formed between the spacers 214.

A metal gate electrode may be deposited into this trench (126). Conventional metal deposition processes may be used, such as ALD, CVD, PVD, electroless plating, or electroplating processes. A planarization process such as CMP may be used to remove excess deposited metal. The metal gate electrode may be formed using any conductive material from which a metal gate electrode may be derived including pure metals, metal alloys, metal oxides, nitrides, oxynitrides, and carbides. When the metal gate electrode will serve as an N-type workfunction metal, the gate electrode preferably has a workfunction that is between about 3.9 eV and about 4.2 eV. N-type materials that may be used to form the metal gate electrode include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the metal gate electrode will serve as a P-type workfunction metal, the gate electrode preferable has a workfunction that is between about 4.9 eV and about 5.2 eV. P-type materials that may be used to form the metal gate electrode include, but are not limited to, ruthenium, palladium, platinum, cobalt, nickel, and conductive metal oxides, e.g., ruthenium oxide. The metal gate electrode should be thick enough to ensure that any material formed on it will not significantly impact its workfunction. Preferably, the metal gate electrode is between about 25 angstroms (Å) and about 600 Å thick, and more preferably is between about 50 Å and about 200 Å thick. Although a few examples of materials that may be used to form the metal gate electrode are described here, that layer may be made from many other materials.

FIG. 9 illustrates the formation of a metal gate electrode 218 on the gate dielectric layer 204. The metal gate electrode 218 is formed of a P-type or an N-type workfunction metal. In some implementation, the metal gate electrode 218 may include at least two layers, one layer functioning as a workfunction metal layer and the second layer functioning as a fill metal layer.

FIGS. 10 to 13 illustrate a process flow for using the invention in another replacement metal gate process. FIG. 10 begins by illustrating a trench formed between a pair of spacers 214 after a dummy gate dielectric and a dummy gate electrode have been etched away. Methods of arriving at this structure are well known in the art. Moving to FIG. 11, several layers are deposited in the trench. The layers include a high-k gate dielectric layer 204, a barrier layer 206 that is formed from a material rich in nitrogen and/or oxygen, and a capping layer 208. Again, during deposition of the high-k dielectric layer, a poor quality transition layer 202 is formed at the interface between the high-k dielectric layer and the substrate.

Turning to FIG. 12, an annealing process is carried out to modify the poor quality transition layer and form a high-quality silicon oxynitride layer 202. The annealing parameters described above may be used here.

Finally, turning to FIG. 13, the capping layer 208, and optionally the barrier layer 206, may be removed and replaced with a metal gate electrode 218. As described above, a P-type or an N-type metal may be used to form the metal gate electrode 218, and in some implementations, the metal gate electrode 218 may include a workfunction metal layer and a fill metal layer. In some implementations of the invention, the barrier layer 206 may not be removed and may remain between the metal gate electrode 218 and the high-k gate dielectric layer 204. A planarization process may also be used to remove excess metal sited atop the ILD layer 216.

Accordingly, a process flow has been described for fabricating a MOS transistor with an improved transition layer between the high-k gate dielectric layer and the semiconductor substrate. As described above, the process flow of the invention enables precise thickness control of the interfacial silicon oxynitride transition layer by varying barrier layer thickness, capping layer thickness, and annealing parameters. The barrier layer includes oxygen and/or nitrogen that is driven down during the anneal to improve the quality of the transition layer. The process disclosed improves bias-temperature reliability of the high-k and metal electrode gate stack. Finally, the process flow of the invention can be used in subtractive as well as replacement metal gate processes.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
depositing a high-k dielectric layer on a substrate;
depositing a barrier layer on the high-k dielectric layer, wherein the barrier layer includes at least one of nitrogen or oxygen;
depositing a capping layer on the barrier layer; and
annealing the substrate to drive the at least one of nitrogen or oxygen to an interface between the high-k dielectric layer and the substrate, wherein the at least one of nitrogen or oxygen modifies a silicon oxynitride layer that has formed at the interface.

2. The method of claim 1, wherein the barrier layer comprises titanium oxynitride or tantalum oxynitride.

3. The method of claim 1, wherein a thickness of the barrier layer ranges from 10 Å to 40 Å.

4. The method of claim 1, wherein the annealing process is carried out at a temperature between around 600° C. and around 1100° C. for a time duration between around 1 seconds and 30 seconds.

5. The method of claim 1, wherein the modification to the silicon oxynitride layer improves the quality of the silicon oxynitride layer and increases a thickness of the silicon oxynitride layer.

6. The method of claim 1, wherein the capping layer comprises polysilicon and a thickness of the capping layer ranges from 100 Å to 600 Å.

7. The method of claim 1, further comprising:
removing the capping layer; and
depositing a metal gate electrode layer on the barrier layer.

8. The method of claim 1, further comprising:
removing the capping layer;
removing the barrier layer; and
depositing a metal gate electrode layer on the high-k dielectric layer.

9. A method comprising:
depositing a high-k dielectric layer on a substrate;
depositing a barrier layer on the high-k dielectric layer, wherein the barrier layer includes at least one of nitrogen or oxygen;
depositing a capping layer on the barrier layer;
annealing the substrate at a temperature that causes at least a portion of the nitrogen or oxygen in the barrier layer to diffuse to an interface between the high-k dielectric layer and the substrate;
etching the high-k dielectric layer, the barrier layer, and the capping layer to form a gate stack;
forming a pair of spacers on laterally opposite sides of the gate stack;
forming diffusion regions in the substrate adjacent to the spacers;
forming an ILD layer on the substrate;
removing the capping layer to form a trench between the spacers; and
depositing a metal gate electrode layer in the trench.

10. The method of claim 9, further comprising removing the barrier layer after removing the capping layer and prior to depositing the metal gate electrode layer in the trench.

11. The method of claim 9, wherein the barrier layer comprises titanium oxynitride or tantalum oxynitride.

12. The method of claim 9, wherein a thickness of the barrier layer ranges from 10 Å to 40 Å.

13. The method of claim 9, wherein the diffused nitrogen or oxygen forms a high-quality silicon oxynitride layer at the interface.

14. The method of claim 9, wherein the annealing of the substrate occurs at a temperature between 600° C. and 1100° C. for a time duration between 1 seconds and 30 seconds.

15. The method of claim 9, wherein the capping layer comprises polysilicon and a thickness of the capping layer ranges from 100 Å to 600 Å.
